(19) United States
(12) Patent Application Publication
(10) Pub. No.: US 2009/0273375 A1
(43) Pub. Date: Nov. 5, 2009

(54) Low-noise LVDS output driver

(76) Inventor: Thomas M. Luich, Puyallup, WA (US)

Correspondence Address: MICHAEL J. URE, 10518 PHIL PLACE, CUPERTINO, CA, 95014, US

(21) Appl. No.: 12/115,453

(22) Filed: May 5, 2008

(51) Int. Cl. H03B 1/00

(52) U.S. Cl. 327/108

(57) ABSTRACT

An LVDS output is described herein that has wideband operation down to 2.5V without degrading spur performance or dramatically increasing die are. A current mirror used in a conventional LVDS output is eliminated in such as way as to reduce noise coupling and produce especially clean output signals.

LVDS (Low Voltage Differential Signaling) is an I/O scheme used in high performance systems requiring differential, low swing signals that are suitable for advanced CMOS technology.

Low swing, differential signaling has its origins in ECL (Emitter Coupled Logic). As the name implies, ECL was originally created using bipolar technology and its output characteristics are particularly well suited for bipolar transistors. Generally, due to its high cost and power, it was only used for the highest performing systems.

As IC technology has advanced, CMOS performance has increased rapidly, mainly due to transistor scaling. As transistors scaled downward, their performance increased, but their operating voltage scaled downward in the same fashion. Though many of the high performance systems using CMOS have progressed beyond the typical ˜200 MHz, rail to rail, CMOS I/O, the power supply levels for these systems has not scaled at the same rate. It therefore became desirable to have CMOS based high performance systems adopt the high performance I/O aspects of ECL and still maintain an I/O scheme that is better suited for CMOS technology.

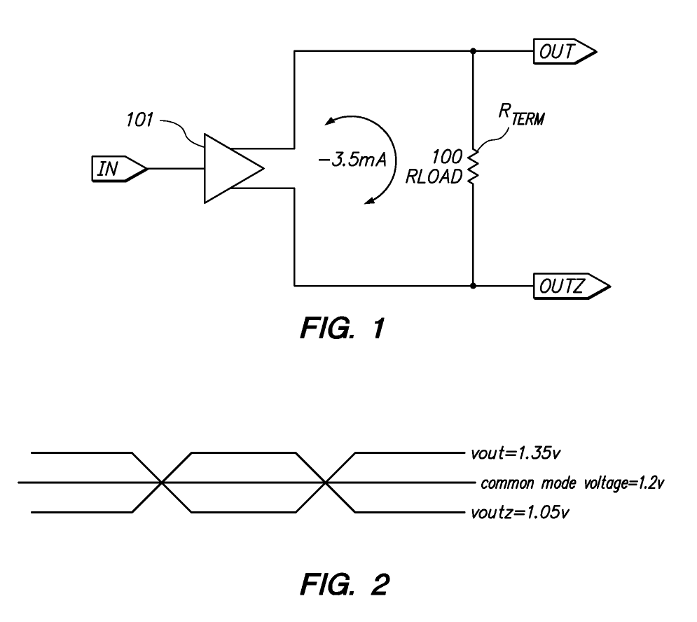

Referring to FIG. 1. a diagram is shown of an LVDS output block 101 including its termination, or load R_{TERM}. FIG. 2 is a diagram showing the required LVDS waveform characteristics. The waveforms show the differential signal that the output block, together with the termination load of 100 ohms, creates. The common mode of the waveform is specified to be 1.2V with a single ended signal swing of 300 mV.

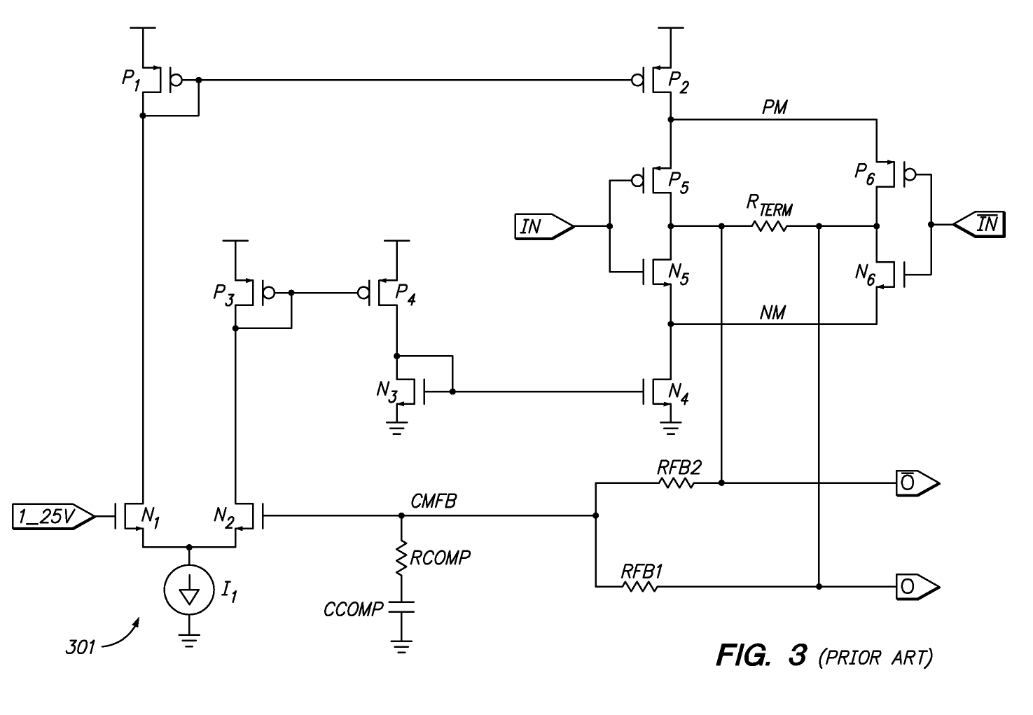

An example of a prior art LVDS output is shown in FIG. 3. This circuit uses a PMOS current source (P1, P2) and an NMOS current sink (N3, N4) to control the current supplied by the inverters (P5/N5, P6/N6), such that 300 mV-350 mV (3 mA-3.5 mA) is realized across the 100 ohm termination resistor.

More particularly, a first transistor pair P5/N5 is coupled in series to form a first inverter, the gates of the transistors P5/N5 being coupled to a non-inverted input signal IN. A second transistor pair P6/N6 is coupled in series to form a second inverter, the gates of the transistors P6/N6 being coupled to an inverted input signal IN bar, or INb. The inverters P5/N5 and P6/N6 are both coupled (via circuit node PM) through a transistor P2 to a supply voltage, and are both coupled (via circuit node PM) through a transistor N4 to ground. An output signal Ob of the inverter P5/N5 and an output signal O of the inverter P6/N6 are coupled together by a termination resistor R_{TERM} having a nominal value of 100 ohms.

A feedback network is formed by resistors RFB1/RFB2 and a filter circuit RCOMP/CCOMP. A feedback circuit node CMFB is coupled via the resistors RFB1 and RFB2 to the respective output signals O and Ob, and is coupled to ground through the series combination of RCOMP/CCOMP. A common-mode feedback signal thus formed at the node CMFB is input to a differential amplifier 301 that includes transistors N1/N2 (connected as a differential pair) and a current source I1. A reference voltage of 1.25V is applied to the other input, of the differential pair N1/N2.

In one leg of the differential amplifier 301, the transistor N1 is coupled through a transistor P1 to the supply voltage. In the opposite leg of the differential amplifier 301, the transistor N2 is coupled through a transistor P3 to the supply voltage. A current through the transistor P1 is mirrored to the transistor P2. A current through the transistor P3 is mirrored to the transistor N4, via transistors P4 and N3.

In FIG. 3, the current is controlled such that a common mode voltage of the output is 1.2V. This mechanism is produced by the differential amplifier (N1, N2, I1) which is referenced to a 1.2V internal voltage (i.e. a bandgap voltage generator) and compared to the common mode voltage swing which is fed back to the amplifier by large valued resistors (RFB1, RFB2).

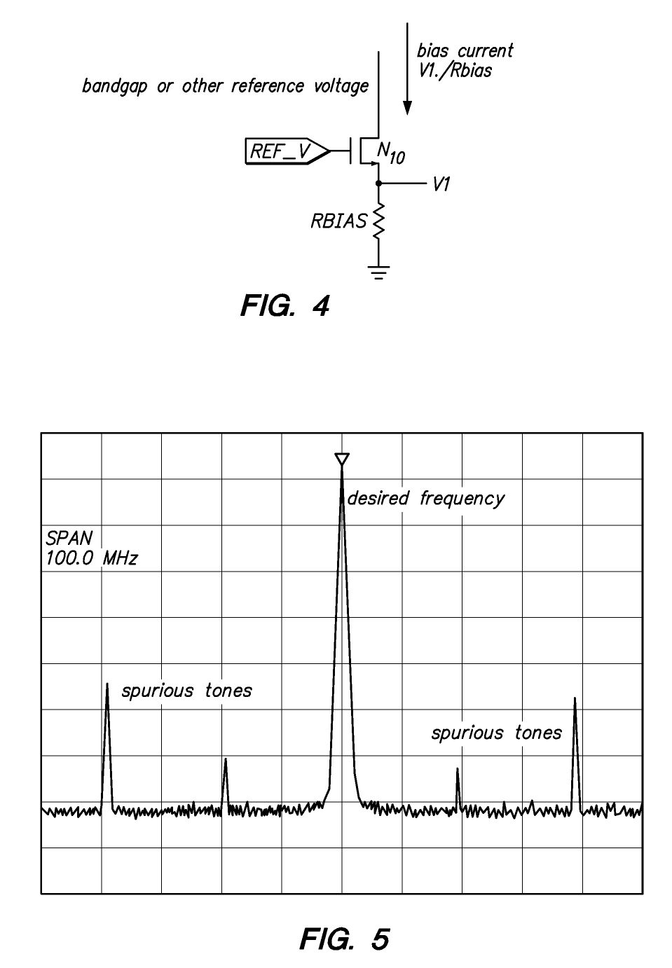

The current source 11 can be generated using a bandgap reference or other reference voltage source that produces a voltage REF_V, a transistor N10, and resistor RBIAS as shown in FIG. 4.

In the prior art, the 3.5 mA controlled output current is set by a bias resistor across which a known voltage is applied, such as the voltage V1 in the typical method shown in FIG. 4. The 3.5 mA output current across the 100 ohm termination resistance yields a 350 mV single ended output voltage swing. The common mode of the differential output voltage, and the current source/sink values are determined by the feedback loop created by the feedback resistors (RFB1, RFB2), the differential amplifier (N1, N2, P1, P3, and I1), and the current mirror source/sink transistors (P1, P2, N3, N4). The feedback loop forces the common mode voltage of the output signal to equal the reference voltage of 1.25 volts, while balancing the current source/sink at 3.5 mA.

Many high performance systems require low noise circuits. Noise can be seen as “jitter” on any edge in the output. Causes of jitter can be internal timing inaccuracies, phase noise, spurious frequencies found in the spectrum, etc. FIG. 5 shows an example of spurious tones (frequencies) found in the output spectrum of a known CMOS driver. The desired frequency is centered on the plot, and the spurious tones are found at offsets of ˜20 and ˜40 MHz. These spurious tones (spurs) supply unwanted energy at frequencies other than the desired frequency, causing jitter.

One source of spurs is internal signals, at frequencies different than the output, leaking to the output through the power supply. In the time domain, this would appear as a small signal added to the VDD of the output. In the case of an oscillator output signal, this small signal is upconverted by the output, and is seen as spurs around the carrier (output frequency).

One way to reduce the signal leakage to the output is to have separate power supply pins, such that the output power supply is isolated from the supply of the internal circuits generating the spurious signals. This approach can be used only if it is possible to add another pin to the circuit.

An LVDS output is described herein that has wideband operation down to 2.5V without degrading spur performance or dramatically increasing die area. A current mirror used in a conventional LVDS output is eliminated in such as way as to reduce noise coupling and produce especially clean output signals.

Other features and advantages will be understood upon reading and understanding the detailed description of exemplary embodiments, found herein below, in conjunction with reference to the drawings, a brief description of which is provided below.

FIG. 1 is a diagram of a known LVDS output driver.

FIG. 2 is a diagram of waveforms associated with the output driver of FIG. 1.

FIG. 3 is a more detailed diagram of the LVDS output driver of FIG. 1.

FIG. 4 is diagram of a current source I1 of FIG. 3.

FIG. 5 is an output spectrum plot of a typical LVDS output driver.

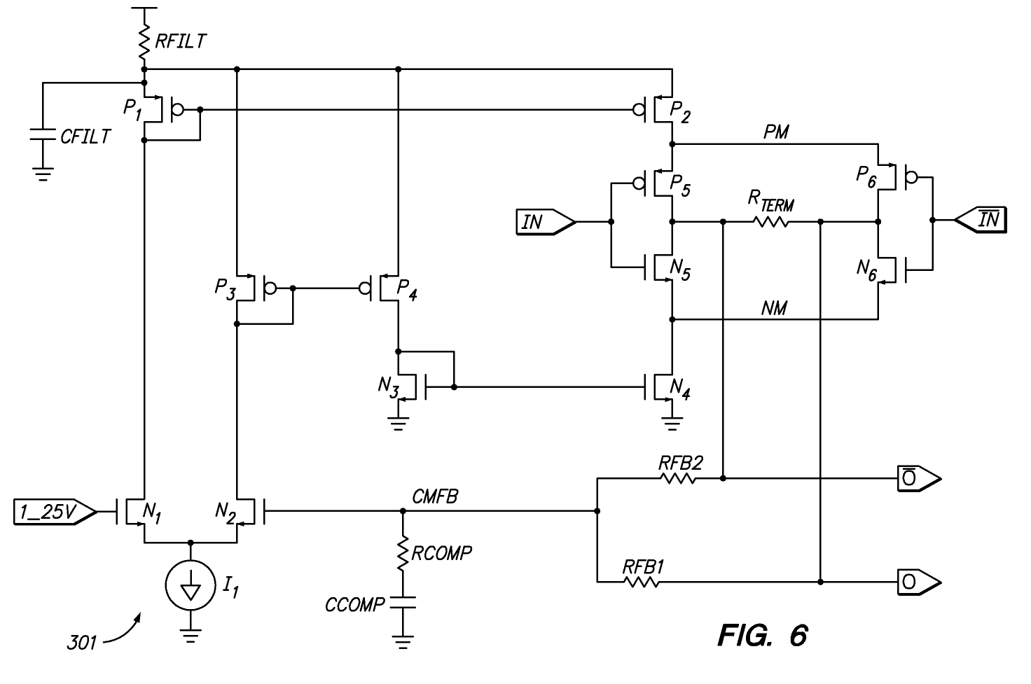

FIG. 6 is a diagram of an LVDS output stage of a suppIy-filtered CMOS driver.

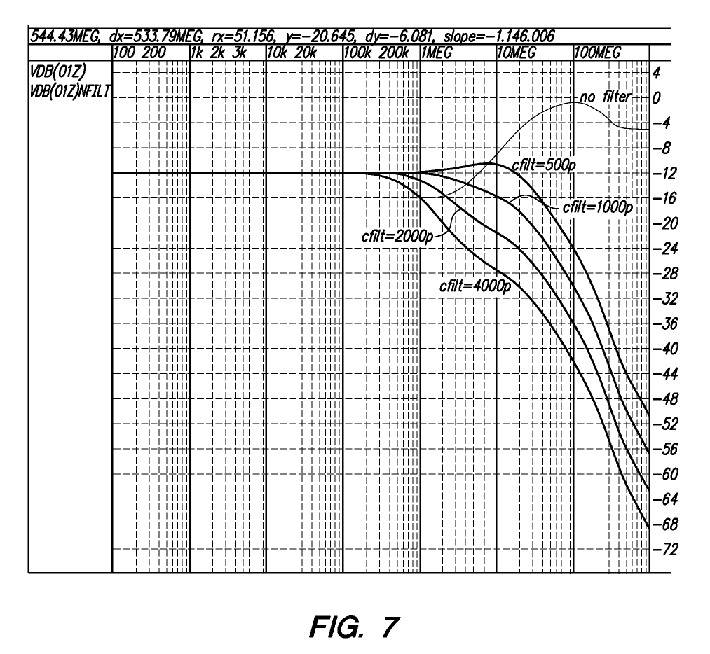

FIG. 7 is a diagram illustrating VDD isolation characteristics of the output stage of FIG. 6.

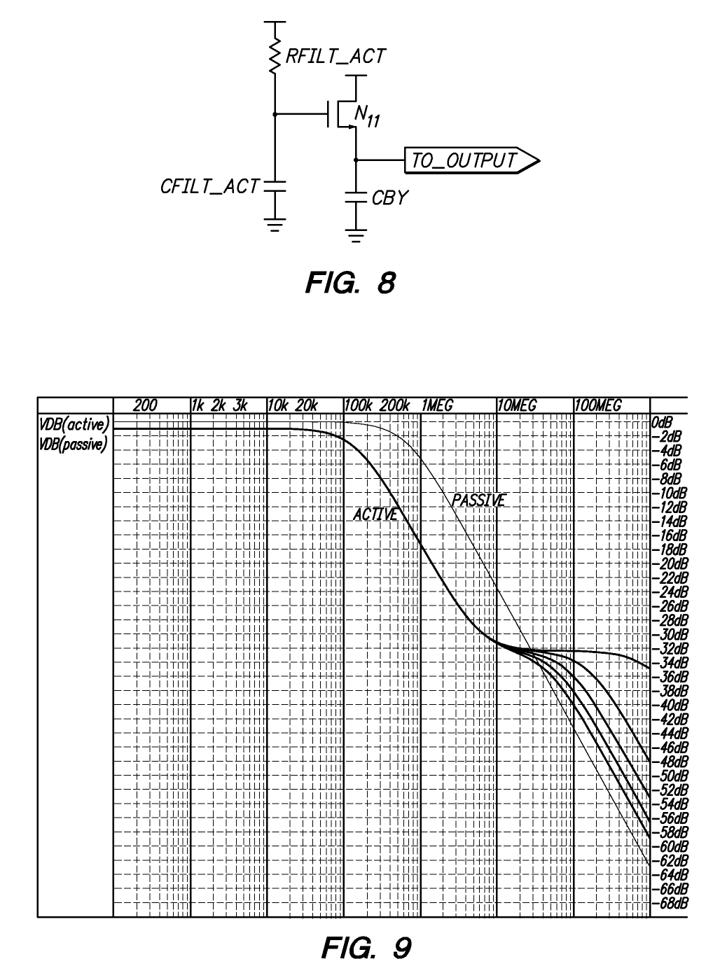

FIG. 8 is a diagram of an active power supply filter that may be used in the LVDS output stage of FIG. 6.

FIG. 9 is a diagram comparing VDD isolation characteristics of the output stage of FIG. 6 using a passive supply filter and using an active supply filter with various different values of CFILT.

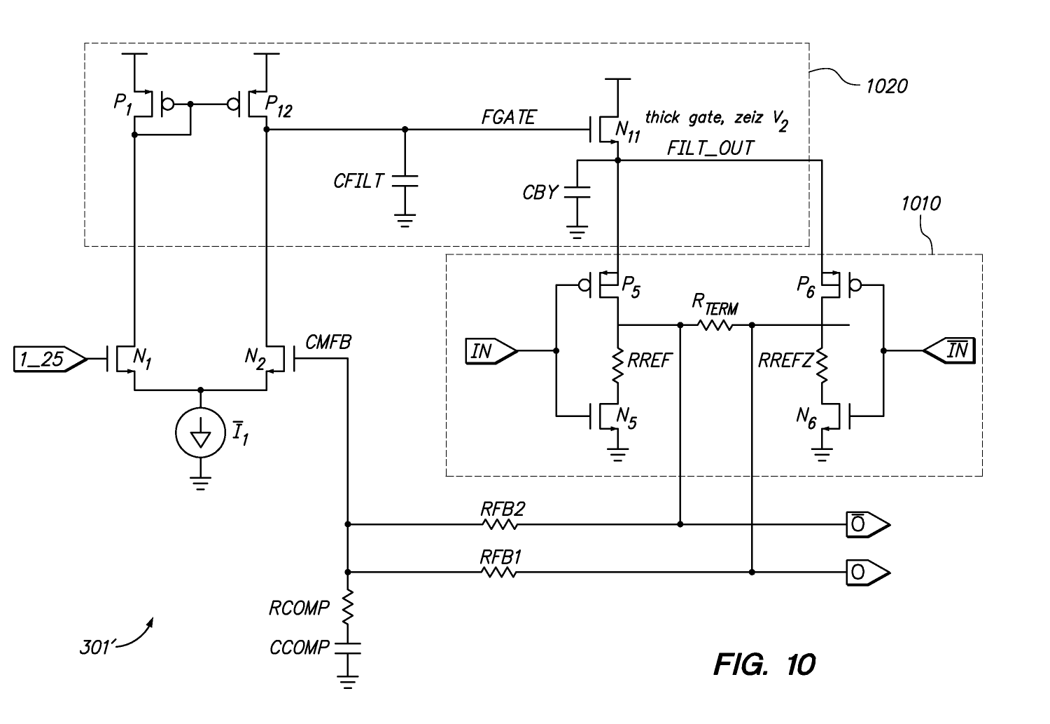

FIG. 10 is a diagram of an LVDS output stage of a supply-filtered CMOS driver in which improved operating margin is achieved as comparted to the LVDS output stage of FIG. 6.

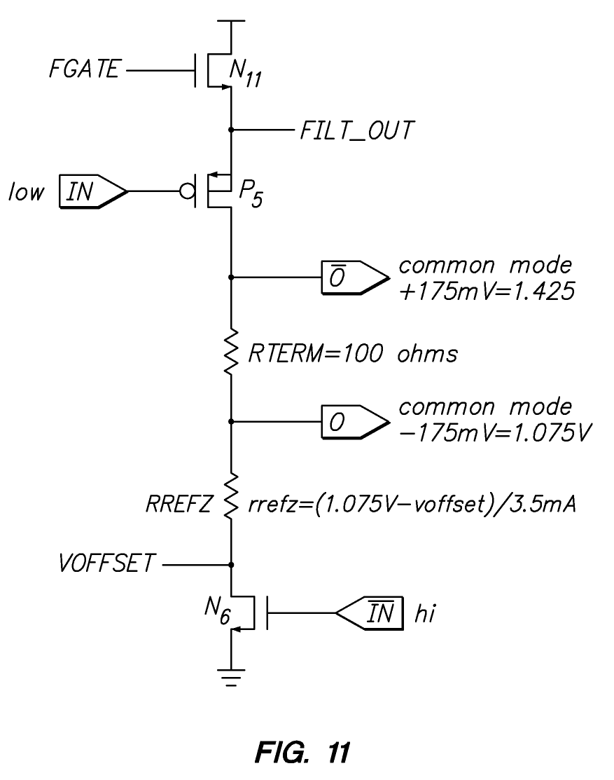

FIG. 11 is a diagram of a portion of the circuit 1010 of FIG. 10.

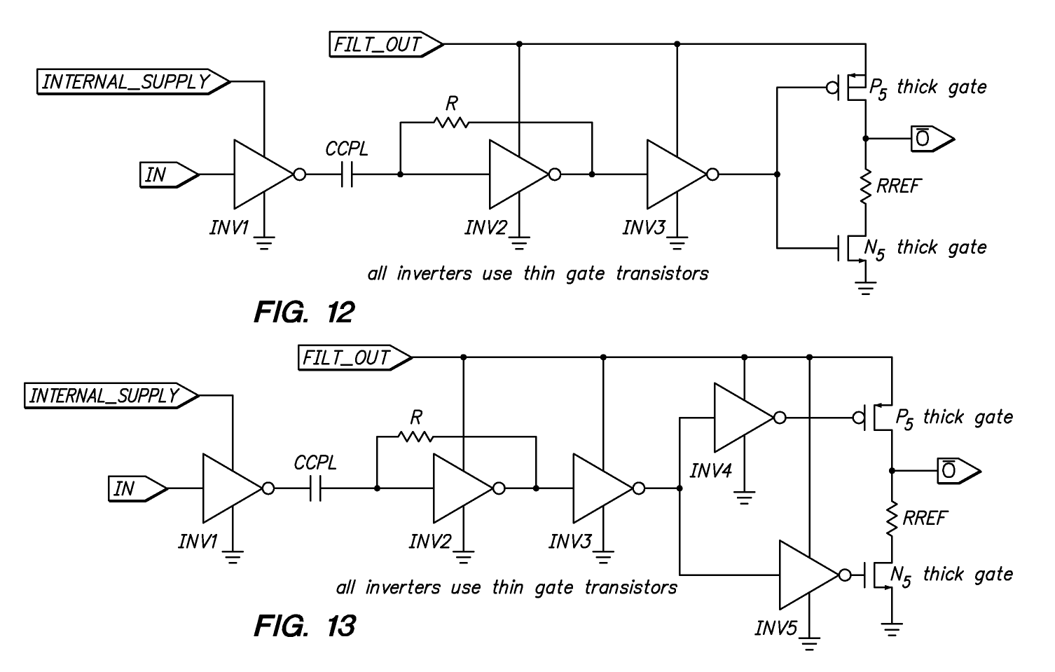

FIG. 12 is a diagram of a supply-filtered LVDS driver with predriver and level shifter circuits.

FIG. 13 is a diagram of an alternative supply-filtered LVDS driver with predriver and level shifter circuits.

There follows a more detailed description of the present invention. Those skilled in the art will realize that the following detailed description is illustrative only and is not intended to be in any way limiting. Other embodiments of the present invention will readily suggest themselves to such skilled persons having the benefit of this disclosure. Reference will now be made in detail to embodiments of the present invention as illustrated in the accompanying drawings. The same reference indicators will be used throughout the drawings and the following detailed description to refer to the same or like parts.

As previously described, signal leakage to the output of an LVDS output driver can undesirably degrade the output signal. In accordance with one aspect of the present LVDS output driver, a filter is inserted between the output and VDD. By inserting a filter between the output and VDD, it is possible to increase the isolation from VDD.

Referring to FIG. 6, a simple RC filter RFILT/CFILT may be inserted between the output and VDD as shown. By inserting the filter in this location, the output current will pass through RFILT, reducing the operating voltage of the output. The resistor value of the filter will therefore need to be low in order to maintain enough operating margin for the output. For example using a 100 ohm resistor will cause a 350 mV operation margin reduction in the output, assuming a 350 mV single ended swing of the output voltage.

It has been found that RFILT has a significant, impact on the output waveform, and must be kept small, since, the higher the value, the larger the drop across it, limiting head room of the output. Furthermore, it may be shown that RFILT further degrades the VDD isolation clue to loss of operating margin. In one example, between RFILT=1 ohm and 130 ohms, the isolation degrades by 5 db at 10 MHz.

FIG. 7 shows the isolation characteristics of the output without a Filter, and with a filter using 60 ohms for RFILT, VDD=2.5V, and various values of CFILT. The plot shows a 20 db improvement over the no filter case using RFILT=60, and CFlLT=4000 p, but an operating margin reduction of 210 mV occurs. Additionally, the 4000 pF capacitor requires large area. For metal to metal capacitors, available in many processes, unit capacitance is typically 1 fF/u², making the 4000 pF capacitor 4 million square microns, (2000 um×2000 um). The area penalty can be reduced using transistor gate capacitance. The improvement will depend on the specific technology.

By adding a transistor to the filter, the issues involving low value RFILT, and high value CFILT, can be mostly mitigated.

FIG. 8 shows an active RC Filter, in contrast to the passive type filter of FIG. 6. The supply voltage V is filtered through a series RC circuit RFILT_ACT/CFILT_ACT, with RFILT_ACT being connected to the supply voltage and CFILT_ACT being connected to ground. However, instead of the filtered supply voltage being taken directly from an intermediate node joining RFILT_ACT and CFILT_ACT (as in the case of a passive supply filter), a source follower stage is provided in the form of a transistor N11. A drain electrode of the transistor N11 is coupled to the supply voltage. The source electrode of the transistor N11 is coupled through a bypass capacitor CBY to ground. The gate electrode of the transistor N11 is coupled to the intermediate node joining RFILT_ACT and CFILT_ACT. The filtered supply voltage output, is now taken at the source electrode of the transistor N11.

In the case of the active filter of FIG. 8, the source follower transistor N11 supplies the large currents required by the output. The filtering is performed at the gate of the source follower, so RFILT_ACT may use a much larger value since no DC or output current flows through it. A much higher RFILT_ACT, will allow a much lower CFILT_ACT to achieve the same bandwidth characteristics.

FIG. 9 shows the bandwidth of both types of filters with the same passive components used above, and RFILT_ACT=100 kohms, CFILT_ACT=10 pF, and various values of CBY. Both filters supply 3.5 mA in this comparison. In this comparison, the active filter has a 3db bandwidth improved by 540 kHz, while the filter capacitor value is reduced from 4000 p to 10 p. It is therefore desirable to use the active filter to mitigate the large device area; however, increased loss of margin is incurred. This loss of operating margin is acceptable if the operating margin may be restored elsewhere in the circuit.

As previously described in relation to FIG. 3, in a conventional LVDS output driver, using two current mirrors in series with the output inverters reduces the operating margin of the inverters by the source to drain voltages required on the current mirrors to maintain linear operation. This loss of operating margin is seen as reduced VDD noise attenuation and degraded output waveforms.

Referring to FIG. 10, a low voltage, supply filtered LVDS output driver is shown. As compared to the circuits of FIG. 3 and FIG. 6, significant changes may be/observed in an inverter portion 1010 of the circuit and in a supply portion 1020 of the circuit.

Within the inverter portion 1010 of the circuit, sources of the transistors N5 and N6 are coupled directly to ground. A resistor RREF is inserted between the source of the transistor P5 and the drain of the transistor N5. Similarly, a resistor RREFZ is inserted between the source of the transistor P6 and the drain of the transistor N6.

Within the supply portion 1020 of the circuit, transistors N1 and N2 of the differential amplifier 301′ are Coupled to the supply voltage through respective transistors P1 and P12. The transistors P1 and P12 are connected such that the current through the transistor P1 is mirrored in the transistor P12. The transistor P12, a capacitor CFILT and a transistor N11 form an active supply filter, an output FILT_OUT of which is applied to the inverter portion 1010 of the circuit. A drain electrode of the transistor N11 is coupled to the supply voltage, and a source electrode of the transistor 11 forms the output FILT_OUT, The source electrodes of the transistors P12 and N11 are coupled together at a circuit node FGATE, which is coupled through the capacitor CFILT to ground.

To achieve low (2.5V) voltage operation, a zero Vt, source follower N11 is used. To achieve 3.3 reliability all transistors are of the thick gate type, present in most modern CMOS processes.

As compared to the circuit of FIG. 3 in particular, in the circuit of FIG. 10, the NMOS current mirror (P4, N3, N4) is removed and the source electrodes of the NMOS transistors N5 and N6 of the driver inverter are connected to ground. The PMOS current mirror P2 of FIG. 3 is replaced by an active supply filter (P12, CFILTER, N11).

The common mode is determined by feedback resistors (RFB1 and RFB2), the differential amplifier 301′, and the source follower (N11), which is the output of the supply filter. The feedback resistors RFB1 and RFB2, which may be on the order of 50 kohms each, feed to a common node (CMFB), which is filtered by RCOMP/CCOMP, and then compared to a 1.25V reference voltage by the differential amplifier 301′. In contrast to the prior art, the differential amplifier 301′ then forces the source electrodes of PMOS transistors P1 and P2 (node FGATE) to the voltage necessary to create a 1.25V common mode voltage on the output. In this way, the source electrodes of transistors N5, N6 and N11 connect directly to low impedance nodes, and no operating margin is lost due to linear requirements of current mirrors. The use of a zero Vt transistor as the output of the filter ensures low voltage operation, and the high impedance of the differential amplifier 301′ forms the resistive component of the filter, forming an RC circuit in combination with CFILT.

The output voltage swing of the output is specified to be 350 mV across the 100 ohm termination resistor, implying a 3.5 mA output current. Since the common mode voltage is forced to be 1.25V, the output low voltage must be the common mode voltage minus 175 mV, or 1.075V. The manner in which the desired output voltage swing is obtained, using resistors RREF and RREFZ, is illustrated in FIG. 11. FIG. 11 shows the output current path of the active on devices for the true/complement sides of the output. With the true side of the output high and the complement side of the output low, a resistance (RREFZ) inserted between the output pad and the NMOS switch (N6) will provide the correct voltage at both true and complement sides of the output. The value of RREFZ will be the desired low voltage of the output minus the offset voltage VOFFSET of the on transistor N6, divided by the current required to yield 350 mV output voltage across a 100 ohm resistor. If N6 is sized such that the offset voltage is small, the value of RREFZ will be on the order of 250 ohms.

In an exemplary embodiment, the circuit of FIG. 10 exhibits minimal sensitivity to variations in VDD over a range of 2.2V to 3.6V.

FIG. 12 shows a portion of the output driver of FIG. 10, together with a predriver circuit formed by a series of inverters INV1, INV2 and INV3. In this configuration, inverter INV1 is constructed using thin gate devices, and uses the internal supply of the overall circuit. This inverter is AC coupled to a biased inverter INV2, which is connected to the supply filter output voltage FlLT_OUT. Such coupling allows the supply filter output voltage to be different than that of the internal supply. The inverter INV3 and the output driver circuit P5/N5 are also connected to the supply filter output voltage FILT_OUT,

FIG. 13 shows an alternate method to drive the output transistors, in this case, additional inverters INV4 and INV5 are added, with each output transistor being individually driven by an inverter. The total number of inverters used to drive the output transistors depends on the process technology used, and the maximum frequency required.

Although embodiments of the present invention have been described in detail, it should be understood that various changes, substitutions and alternations can be made without departing from the spirit and scope of the inventions as defined by the appended claims.

What is claimed is:

1. An integrated circuit output driver fabricated in a MOS process, comprising:
a predriver circuit;
an output driver circuit coupled to the predriver circuit; and
a low-pass power supply filter coupled to the output driver circuit.

2. The apparatus of claim 1, wherein the power supply filter is a passive power supply filter.

3. The apparatus of claim 2, wherein the power supply filter comprises an RC circuit.

4. The apparatus of claim 1, wherein the power supply filter is an active power supply filter.

5. The apparatus of claim 2, wherein the power supply filter comprises an RC circuit and a source-follower transistor.

6. The apparatus of claim 1, wherein the output driver produces LVDS signal levels.

7. An integrated circuit output driver fabricated in a MOS process, comprising:
a predriver circuit; and
a driver circuit coupled to the predriver circuit, the driver circuit comprising:
a first transistor pair coupled in series between a positive supply node a negative supply node to form a first inverter;
a second transistor pair coupled in series between the positive supply node and the negative supply node to form a second inverter; and
a load resistor coupled between, an output node of the first inverter and an output node of the second inverter;
wherein a transistor of the first transistor pair and a transistor of the second transistor pair are connected directly to the negative supply node.

8. The apparatus of claim 7, wherein the driver circuit further comprises a first resistor coupled in series between transistors of the first transistor pair and a second resistor coupled in series between transistors the second transistor pair such that a specified load current produces a specified voltage swing at an output node.

9. The apparatus of claim 8, wherein the specified load current is an LVDS load current, and the specified voltage swing is an LVDS voltage swing.

10. The apparatus of claim 8, further comprising an active power supply filter that produces a filtered power supply output, the filtered power supply output being coupled to said supply node.

11. The apparatus of claim 8, wherein the power supply filter is an active power supply filter comprising a transistor.

12. The apparatus of claim 11, wherein the power supply filter comprises an RC circuit and the transistor of the power supply filter is a source-follower transistor.

13. The apparatus of claim 11, comprising:
a common mode voltage feedback circuit coupled to the output node of the first inverter and to the output node of the second inverter that produces a common mode feedback signal indicative of a common mode voltage across the load resistor; and
a differential amplifier coupled to the common mode feedback signal.

14. The apparatus of claim 13, wherein an output signal of the differential amplifier is coupled to a gate terminal of the transistor of the power supply filter.
